(19) United States
(12) Patent Application Publication
(10) Pub. No.: US 2023/0358605 A1
(43) Pub. Date: Nov. 9, 2023

(54) MATCHING METHOD OF LIGHT SOURCE PARAMETERS

(71) Applicant: United Microelectronics Corp., Hsinchu (TW)

(72) Inventors: Sheng Lung Teng, Tainan City (TW); Guo Xin Hu, Tainan City (TW); Chih-Hsien Tang, Taipei City (TW)

(73) Assignee: United Microelectronics Corp., Hsinchu (TW)

(21) Appl. No.: 17/751,684

(22) Filed: May 24, 2022

(30) Foreign Application Priority Data
May 4, 2022 (TW) 111116762

(51) Int. Cl. G01J 1/44

(52) U.S. Cl. CPC G01J 1/44; G01J 2001/4247

(57) ABSTRACT

A matching method of light source parameters includes the following. First light source parameter data of a first exposure machine and second light source parameter data of a second exposure machine corresponding to the first light source parameter data are collected. Whether a second light intensity distribution included in the second light source parameter data meets a first light intensity distribution included in the first light source parameter data is determined. If the second light intensity distribution meets the first light intensity distribution, a simulated exposure process is performed by using the first light source parameter data and the second light source parameter data. Second simulated exposure data obtained by using the second light source parameter data is compared with first simulated exposure data obtained by using the first light source parameter data to determine whether the second simulated exposure data meets the first simulated exposure data.

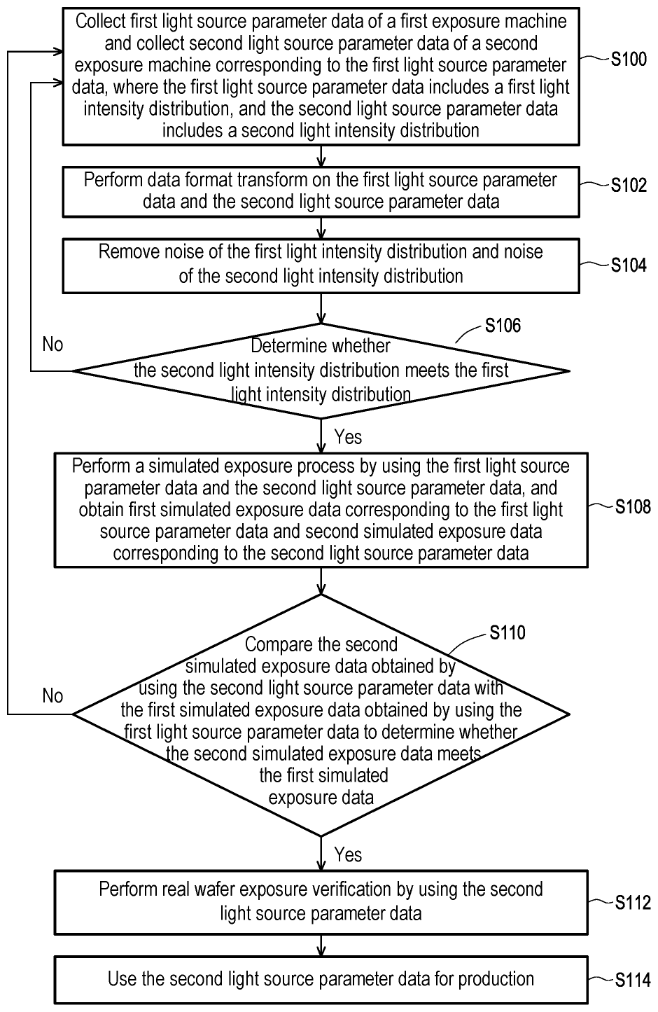

### CROSS-REFERENCE TO RELATED APPLICATION

This application claims the priority benefit of Taiwanese application no. 111116762, filed on May 4, 2022. The entirety of the above-mentioned patent application is hereby incorporated by reference herein and made a part of this specification.

### BACKGROUND

### Technical Field

The disclosure relates to a semiconductor process. In particular, the disclosure relates to a matching method of light source parameters.

### DESCRIPTION OF RELATED ART

Currently during process porting, light source parameters between different exposure machines are matched by directly using multiple times of real wafer exposure. However, the current matching method of light source parameters is relatively time-consuming and costly. Therefore, how to reduce the time and cost of light source parameter matching is an issue to be continuously focused on.

### SUMMARY

The disclosure provides a matching method of light source parameters, in which the time and cost of light source parameter matching can be reduced.

The disclosure proposes a matching method of light source parameters, including the following. First light source parameter data of a first exposure machine is collected and second light source parameter data of a second exposure machine corresponding to the first light source parameter data is collected. The first light source parameter data includes a first light intensity distribution, and the second light source parameter data includes a second light intensity distribution. Whether the second light intensity distribution meets the first light intensity distribution is determined. If the second light intensity distribution meets the first light intensity distribution, a simulated exposure process is performed by using the first light source parameter data and the second light source parameter data, and first simulated exposure data corresponding to the first light source parameter data and second simulated exposure data corresponding to the second light source parameter data are obtained. The second simulated exposure data obtained by using the second light source parameter data is compared with the first simulated exposure data obtained by using the first light source parameter data to determine whether the second simulated exposure data meets the first simulated exposure data.

In the matching method of light source parameters according to an embodiment of the disclosure, the first light source parameter data may further include light source shape data corresponding to the first light intensity distribution and a numerical aperture (NA) corresponding to the first light intensity distribution.

In the matching method of light source parameters according to an embodiment of the disclosure, the light source shape data may include a light source shape, a degree of coherence (Sigma (σ)), or a combination thereof.

In the matching method of light source parameters according to an embodiment of the disclosure, the second light source parameter data may further include light source shape data corresponding to the second light intensity distribution and a numerical aperture corresponding to the second light intensity distribution.

In the matching method of light source parameters according to an embodiment of the disclosure, the light source shape data may include a light source shape, a degree of coherence, or a combination thereof.

In the matching method of light source parameters according to an embodiment of the disclosure, the first light intensity distribution may include a slice intensity distribution.

In the matching method of light source parameters according to an embodiment of the disclosure, the second light intensity distribution may include a slice intensity distribution.

In the matching method of light source parameters according to an embodiment of the disclosure, if the second light intensity distribution does not meet the first light intensity distribution, after a light source parameter of the second exposure machine is adjusted, the second light source parameter data corresponding to the adjusted light source parameter is collected.

In the matching method of light source parameters according to an embodiment of the disclosure, if the second simulated exposure data meets the first simulated exposure data, the second light source parameter data is used for production.

In the matching method of light source parameters according to an embodiment of the disclosure, after it is determined that the second simulated exposure data meets the first simulated exposure data, and before the second light source parameter data is used for production, real wafer exposure verification may be performed by using the second light source parameter data.

In the matching method of light source parameters according to an embodiment of the disclosure, if the second simulated exposure data does not meet the first simulated exposure data, after a light source parameter of the second exposure machine is adjusted, the second light source parameter data corresponding to the adjusted light source parameter is collected.

In the matching method of light source parameters according to an embodiment of the disclosure, the first simulated exposure data may include an exposure pattern contour, optical proximity data, or a combination thereof.

In the matching method of light source parameters according to an embodiment of the disclosure, the exposure pattern contour may include a weak pattern contour.

In the matching method of light source parameters according to an embodiment of the disclosure, the second simulated exposure data may include an exposure pattern contour, optical proximity data, or a combination thereof.

In the matching method of light source parameters according to an embodiment of the disclosure, the exposure pattern contour may include a weak pattern contour.

According to an embodiment of the disclosure, the matching method of light source parameters may further include the following. Before whether the second light intensity distribution meets the first light intensity distribution is determined, data format transform is performed on the first light source parameter data and the second light source parameter data.

According to an embodiment of the disclosure, the matching method of light source parameters may further include the following. Before whether the second light intensity distribution meets the first light intensity distribution is determined, noise of the first light intensity distribution and noise of the second light intensity distribution are removed.

Based on the foregoing, in the matching method of light source parameters according to the embodiments of the disclosure, the simulated exposure process is performed using the first light source parameter data and the second light source parameter data. In addition, the second simulated exposure data obtained by using the second light source parameter data is compared with the first simulated exposure data obtained by using the first light source parameter data to determine whether the second simulated exposure data meets the first simulated exposure data. Accordingly, the number of times of real wafer exposure can be reduced, thereby reducing the time and cost of light source parameter matching.

To make the aforementioned more comprehensible, several embodiments accompanied with the FIGURE are described in detail as follows.

### BRIEF DESCRIPTION OF THE FIGURE

The FIGURE is included to provide a further understanding of the disclosure, and is incorporated in and constitutes a part of this specification. The FIGURE illustrates exemplary embodiments of the disclosure and, together with the description, serves to explain the principles of the disclosure.

The FIGURE is a flowchart of a matching method of light source parameters according to some embodiments of the disclosure.

### DESCRIPTION OF THE EMBODIMENTS

The FIGURE is a flowchart of a matching method of light source parameters according to some embodiments of the disclosure.

With reference to the FIGURE, step S100 is performed, in which first light source parameter data of a first exposure machine is collected and second light source parameter data of a second exposure machine corresponding to the first light source parameter data is collected. The first light source parameter data includes a first light intensity distribution, and the second light source parameter data includes a second light intensity distribution. In some embodiments, the first light intensity distribution may include a slice intensity distribution. In some embodiments, the second light intensity distribution may include a slice intensity distribution. In some embodiments, the slice intensity distribution may be an intensity distribution on a tangent passing through the center of the light source shape.

In some embodiments, the first light source parameter data may include light source shape data corresponding to the first light intensity distribution and a numerical aperture corresponding to the first light intensity distribution. In some embodiments, the second light source parameter data may include light source shape data corresponding to the second light intensity distribution and a numerical aperture corresponding to the second light intensity distribution. In some embodiments, the light source shape data may include a light source shape, a degree of coherence, or a combination thereof.

Next, step S102 may be performed, in which data format transform is performed on the first light source parameter data and the second light source parameter data. Accordingly, the formats of the first light source parameter data and the second light source parameter data can be unified, and the formats of the first light source parameter data and the second light source parameter data can be converted into formats compatible with simulation software.

Then, step S104 may be performed, in which noise of the first light intensity distribution and noise of the second light intensity distribution are removed. Accordingly, the interference by noise can be reduced.

Next, step S106 may be performed to determine whether the second light intensity distribution meets the first light intensity distribution. In some embodiments, “determining whether the second light intensity distribution meets the first light intensity distribution” indicates “calculating a similarity between the second light intensity distribution and the first light intensity distribution and determining whether the similarity exceeds a predetermined threshold”. In addition, if the similarity exceeds the predetermined threshold, it is determined that the second light intensity distribution meets the first light intensity distribution. In some embodiments, determining whether the second light intensity distribution meets the first light intensity distribution may include comparing a distribution curve of the second light intensity distribution with a distribution curve of the first light intensity distribution.

In addition, if the second light intensity distribution meets the first light intensity distribution, a simulated exposure process is performed by using the first light source parameter data and the second light source parameter data, and first simulated exposure data corresponding to the first light source parameter data and second simulated exposure data corresponding to the second light source parameter data are obtained (step S108). In some embodiments, the simulated exposure process may be performed by simulation software. In some embodiments, the first simulated exposure data may include an exposure pattern contour, optical proximity data, or a combination thereof. In some embodiments, the second simulated exposure data may include an exposure pattern contour, optical proximity data, or a combination thereof. Moreover, the exposure pattern contour is a contour of the simulated exposure pattern obtained by the simulated exposure process. Furthermore, the optical proximity data may include through pitch optical proximity data. In some embodiments, the exposure pattern contour may include a weak pattern contour. In this embodiment, the “weak pattern” indicates an exposure pattern with a low process window.

In addition, if the second light intensity distribution does not meet the first light intensity distribution, after a light source parameter of the second exposure machine is adjusted, the second light source parameter data corresponding to the adjusted light source parameter is collected (step S100).

Furthermore, after the simulated exposure process is performed (step S108), step S110 is performed, in which the second simulated exposure data obtained by using the second light source parameter data is compared with the first simulated exposure data obtained by using the first light source parameter data to determine whether the second simulated exposure data meets the first simulated exposure data. In some embodiments, “determining whether the second simulated exposure data meets the first simulated exposure data” indicates “calculating a similarity between the second simulated exposure data and the first simulated exposure data and determining whether the similarity exceeds a predetermined threshold”. In addition, if the similarity exceeds the predetermined threshold, it is determined that the second simulated exposure data meets the first simulated exposure data.

In addition, if the second simulated exposure data meets the first simulated exposure data, the second light source parameter data is used for production (step S114). Moreover, if the second simulated exposure data does not meet the first simulated exposure data, after the light source parameter of the second exposure machine is adjusted, the second light source parameter data corresponding to the adjusted light source parameter is collected (step S100).

In some embodiments, after it is determined that the second simulated exposure data meets the first simulated exposure data (step S110), and before the second light source parameter data is used for production (step S114), real wafer exposure verification may be performed by using the second light source parameter data (step S112). In some embodiments, if the result of the real wafer exposure verification meets the expectation, the second light source parameter data is used for production (step S114). In some embodiments, if the result of the real wafer exposure verification does not meet the expectation, after the light source parameter of the second exposure machine is adjusted, the second light source parameter data corresponding to the adjusted light source parameter is collected (step S100). In some other embodiments, step S112 may be omitted.

As can be known based on the embodiments above, in the matching method of light source parameters, the simulated exposure process is performed by using the first light source parameter data and the second light source parameter data. In addition, the second simulated exposure data obtained by using the second light source parameter data is compared with the first simulated exposure data obtained by using the first light source parameter data to determine whether the second simulated exposure data meets the first simulated exposure data. Accordingly, the number of times of real wafer exposure can be reduced, thereby reducing the time and cost of light source parameter matching.

In summary of the foregoing, in the matching method of light source parameters of the embodiments above, the number of times of real wafer exposure can be reduced by the simulated exposure process, thereby reducing the time and cost of light source parameter matching.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A matching method of light source parameters, the method comprising:
collecting first light source parameter data of a first exposure machine and collecting second light source parameter data of a second exposure machine corresponding to the first light source parameter data, wherein the first light source parameter data comprises a first light intensity distribution, and the second light source parameter data comprises a second light intensity distribution;
determining whether the second light intensity distribution meets the first light intensity distribution;
if the second light intensity distribution meets the first light intensity distribution, performing a simulated exposure process by using the first light source parameter data and the second light source parameter data, and obtaining first simulated exposure data corresponding to the first light source parameter data and second simulated exposure data corresponding to the second light source parameter data; and
comparing the second simulated exposure data obtained by using the second light source parameter data with the first simulated exposure data obtained by using the first light source parameter data to determine whether the second simulated exposure data meets the first simulated exposure data.

2. The method of claim 1, wherein the first light source parameter data further comprises light source shape data corresponding to the first light intensity distribution and a numerical aperture corresponding to the first light intensity distribution.

3. The method of claim 2, wherein the light source shape data comprises a light source shape, a degree of coherence, or a combination thereof.

4. The method of claim 1, wherein the second light source parameter data further comprises light source shape data corresponding to the second light intensity distribution and a numerical aperture corresponding to the second light intensity distribution.

5. The method of claim 4, wherein the light source shape data comprises a light source shape, a degree of coherence, or a combination thereof.

6. The method of claim 1, wherein the first light intensity distribution comprises a slice intensity distribution.

7. The method of claim 1, wherein the second light intensity distribution comprises a slice intensity distribution.

8. The method of claim 1, wherein
if the second light intensity distribution does not meet the first light intensity distribution, after a light source parameter of the second exposure machine is adjusted, the second light source parameter data corresponding to the adjusted light source parameter is collected.

9. The method of claim 1, wherein
if the second simulated exposure data meets the first simulated exposure data, the second light source parameter data is used for production.

10. The method of claim 9, wherein
after it is determined that the second simulated exposure data meets the first simulated exposure data, and before the second light source parameter data is used for production, real wafer exposure verification is performed by using the second light source parameter data.

11. The method of claim 1, wherein
if the second simulated exposure data does not meet the first simulated exposure data, after a light source parameter of the second exposure machine is adjusted, the second light source parameter data corresponding to the adjusted light source parameter is collected.

12. The method of claim 1, wherein the first simulated exposure data comprises an exposure pattern contour, optical proximity data, or a combination thereof.

13. The method of claim 12, wherein the exposure pattern contour comprises a weak pattern contour.

14. The method of claim 1, wherein the second simulated exposure data comprises an exposure pattern contour, optical proximity data, or a combination thereof.

15. The method of claim 14, wherein the exposure pattern contour comprises a weak pattern contour.

16. The method of claim 1, further comprising:
before determining whether the second light intensity distribution meets the first light intensity distribution, performing data format transform on the first light source parameter data and the second light source parameter data.

17. The method of claim 1, further comprising:
before determining whether the second light intensity distribution meets the first light intensity distribution, removing noise of the first light intensity distribution and noise of the second light intensity distribution.
